(19) United States
(12) Patent Application Publication
(10) Pub. No.: US 2013/0046504 A1
(43) Pub. Date: Feb. 21, 2013

(54) COMPUTING DEVICE, STORAGE MEDIUM, AND METHOD FOR TESTING INTEGRITY OF SIGNALS TRANSMITTED FROM HARD DISK INTERFACES

(71) Applicants: HUI-CHI LO, Tu-Cheng (TW); HSIEN-CHUAN LIANG, Tu-Cheng (TW); JUI-HSIUNG HO, Tu-Cheng (TW); SHOU-KUO HSU, Tu-Cheng (TW); CHENG-CHUNG HUANG, Tu-Cheng (TW); CHENG-HSIEN LEE, Tu-Cheng (TW)

(72) Inventors: HUI-CHI LO, Tu-Cheng (TW); HSIEN-CHUAN LIANG, Tu-Cheng (TW); JUI-HSIUNG HO, Tu-Cheng (TW); SHOU-KUO HSU, Tu-Cheng (TW); CHENG-CHUNG HUANG, Tu-Cheng (TW); CHENG-HSIEN LEE, Tu-Cheng (TW)

(73) Assignee: HON HAI PRECISION INDUSTRY CO., LTD., Tu-Cheng (TW)

(21) Appl. No.: 13/483,055

(22) Filed: May 30, 2012

(30) Foreign Application Priority Data
Aug. 18, 2011 (TW) 100129481

(51) Int. Cl. G06F 19/00; G01R 31/28

(52) U.S. Cl. 702/117

(57) ABSTRACT

In a method for testing integrity of signals transmitted from hard disk interfaces using a computing device, the computing device connects to an oscilloscope and a mechanical arm that is equipped with a test fixture. The mechanical arm controls the test fixture to make contact with one of the hard disk interfaces to be tested. The method adjusts an intensity grade of the signals through the hard disk interface, and controls the hard disk interface to produce a signal corresponding to the adjusted intensity grade. The test fixture obtains the signal from the hard disk interface, and the oscilloscope measures one or more test parameters of the signal. The method analyzes values of the test parameters to find an optimal signal, determines an intensity grade of the optimal signal as a driving parameter of the hard disk interface, and generates a test report of the hard disk interfaces.

### BACKGROUND

1. Technical Field

Embodiments of the present disclosure relate to signal test systems and methods, and particularly to a computing device, a storage medium, and a method for testing the integrity of signals transmitted from hard disk interfaces.

2. Description of Related Art

Hard disk interfaces are equipped in various electronic devices such as computers, servers and other data processing devices. In a typical electronic device, each of the hard disk interfaces is used to connect a respective hard disk drive of the electronic device to, e.g., a processor included in another electronic device. Each of the hard disk drives may generate signals when data is exchanged between the hard disk drive and the processor, and the signals are transmitted to the processor through the corresponding hard disk interface. The signals output from each hard disk interface of the electronic device may be measured to test whether the hard disk interface is workable. However, such a test operation is usually performed manually, and is time consuming. Also, the efficiency and accuracy of the test operation cannot be ensured.

### BRIEF DESCRIPTION OF THE DRAWINGS

FIG. 1 is a block diagram of one embodiment of a computing device that includes a signal integrity testing system, and showing an application environment of the computing device.

FIG. 2 is a flowchart of one embodiment of a method for testing the integrity of signals transmitted from hard disk interfaces of an electronic device, using the computing device of FIG. 1.

### DETAILED DESCRIPTION

The present disclosure, including the accompanying drawings, is illustrated by way of examples and not by way of limitation. It should be noted that references to “an” or “one” embodiment in this disclosure are not necessarily to the same embodiment, and such references can mean “at least one.”

In the present disclosure, the word “module,” as used herein, refers to logic embodied in hardware or firmware, or to a collection of software instructions, written in a program language. In one embodiment, the program language may be Java, C, or assembly. One or more software instructions in the modules may be embedded in firmware, such as in an erasable-programmable read-only memory (EPROM). The modules described herein may be implemented as either software and/or hardware modules, and may be stored in any type of non-transitory computer-readable medium or other storage device. Some non-limiting examples of non-transitory computer-readable mediums include compact discs (CDs), digital versatile discs (DVDs), Flash memory, and hard disk drives.

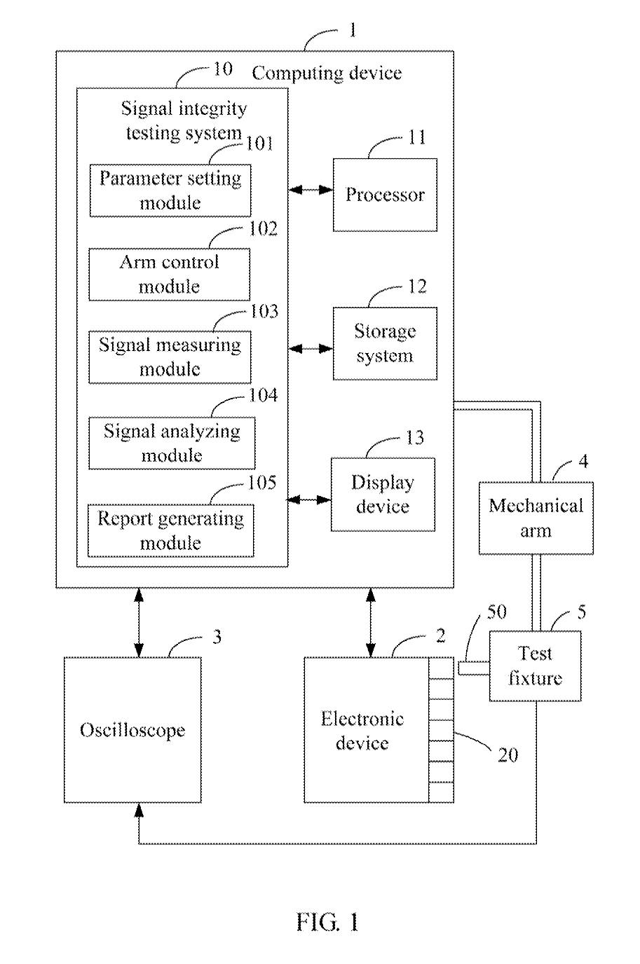

FIG. 1 is a block diagram showing one embodiment of a computing device 1 that includes a signal integrity testing system 10. In the embodiment, the computing device 1 may further include at least one processor 11, a storage system 12 and a display device 13. The computing device 1 electrically connects to an electronic device 2 under test through a serial port (e.g., a COM port) of the computing device 1, and electrically connects to an oscilloscope 3 through a first general purpose interface bus (GPIB). The computing device 1 further mechanically and electrically connects to a mechanical arm 4 that is equipped with a test fixture 5 having a probe 50. The test fixture 5 electrically connects to the oscilloscope 3 through a second GPIB.

In one embodiment, the electronic device 2 is a computer, a server, or a data processing device, and includes a plurality of hard disk interfaces 20. In one embodiment, each of the hard disk interfaces 20 is a serial attached small computer system (SAS) interface or a serial advanced technology attachment (SATA) interface, and is ordinarily used to, inter alia, transmit one or more signals generated by the electronic device 2 to another electronic device, such as the computing device 1. When the probe 50 of the test fixture 5 is electrically connected to one of the hard disk interfaces 20, one or more signals output from the hard disk interface 20 are transmitted to the oscilloscope 3, and the computing device 1 can measure the one or more signals using the oscilloscope 3. In the following description, unless the context indicates otherwise, it is assumed (for the sake of simplicity) that each hard disk interface 20 outputs only one signal.

The signal integrity testing system 10 may include a plurality of functional modules that are stored in the storage system 12 and executed by the at least one processor 11. In one embodiment, the storage system 12 may be an internal storage system, such as a random access memory (RAM) for temporary storage of information, and/or a read only memory (ROM) for permanent storage of information. The storage system 12 may also be an external storage system, such as an external hard disk, a storage card, or a data storage medium.

In one embodiment, the signal integrity testing system 10 includes a parameter setting module 101, an arm control module 102, a signal measuring module 103, a signal analyzing module 104, and a report generating module 105. The modules 101-105 may comprise computerized instructions in the form of one or more programs that are stored in the storage system 12 and executed by the at least one processor 11.

The parameter setting module 101 sets a group of test parameters for evaluating the integrity of the signals transmitted from the hard disk interfaces 20; and also sets an intensity grade range for the signals, and a total number (denoted as “X”) of tests for testing the signal of each hard disk interface 20. In one embodiment, the test parameters may include a phase value, a jitter value, a period value, a frequency value, and a rising time and a falling time of the signal of each hard disk interface 20. The intensity grade range for the signals encompasses a finite set of different intensity characteristics of the signals, with each intensity characteristic having a predefined graded scale. In one embodiment, the intensity grade range includes a phase grade range, a jitter grade range, and a signal emphasis grade range for the signals. If each of the phase grade range, the jitter grade range and the signal emphasis grade range is defined as a graded scale ranging from grade one to grade three, the total number X of tests is set as X=3*3*3=9. If each of the phase grade range, the jitter grade range and the signal emphasis grade range is defined as a graded scale ranging from grade one to grade five, the total number X of tests is set as X=5*5*5=125.

The arm control module 102 controls the probe 50 of the test fixture 5 to make contact with each of the hard disk interfaces 20 using the mechanical arm 4. In the embodiment, the arm control module 102 generates a command to drive the mechanical arm 4 to control the probe 50 of the test fixture 5 to touch any one of the hard disk interfaces 20 to be tested.

The signal measuring module 103 adjusts the intensity grade of the signals generated by the electronic device 2 and subsequently transmitted through the hard disk interfaces 20. In particular, the signal measuring module 103 controls, via the serial port, each hard disk interface 20 to produce a signal corresponding to the adjusted intensity grade. Once the signal corresponding to the adjusted intensity grade is produced, in one embodiment, the signal measuring module 103 can increase the intensity grade of the signal by strengthening the signal, and decrease the intensity grade of the signal by weakening the signal. Thus for the above-described embodiment, each of the phase grade, the jitter grade, and the signal emphasis grade is able to be adjusted as required. The signal measuring module 103 controls the test fixture 5 to obtain the signal produced by the hard disk interface 20; and the signal measuring module 103 measures a value of each of the test parameters of the signal using the oscilloscope 3.

The signal measuring module 103 records the measured values of the test parameters for the hard disk interface 20 in a predefined file, such as an EXCEL format file, and stores the predefined file in the storage system 12. The signal measuring module 103 increases a test serial number (denoted generically as “Y”) by one, i.e., Y′=Y+1, when each set of measured values of the test parameters are recorded in the predefined file. The signal measuring module 103 also determines whether the latest test serial number Y′ is equal to the total number X of tests.

When the latest test serial number Y′ is equal to the total number X of tests, the signal analyzing module 104 analyzes all the measured values of the test parameters of the hard disk interface 20 to find a form of the signal which has an optimal signal integrity. In the embodiment, the form of the signal which has the optimal signal integrity is defined as the form of the signal which has a minimum jitter value or a minimum phase value. The signal analyzing module 104 then determines which intensity grade yielded the form of the signal with the optimal signal integrity, and defines that intensity grade as a driving parameter of the hard disk interface 20.

The report generating module 105 generates a test report of the hard disk interfaces 20 by integrating the defined driving parameters of all of the hard disk interfaces 20, stores the test report of the hard disk interfaces 20 in the storage system 12, and displays the test report of the hard disk interfaces 20 on the display device 13.

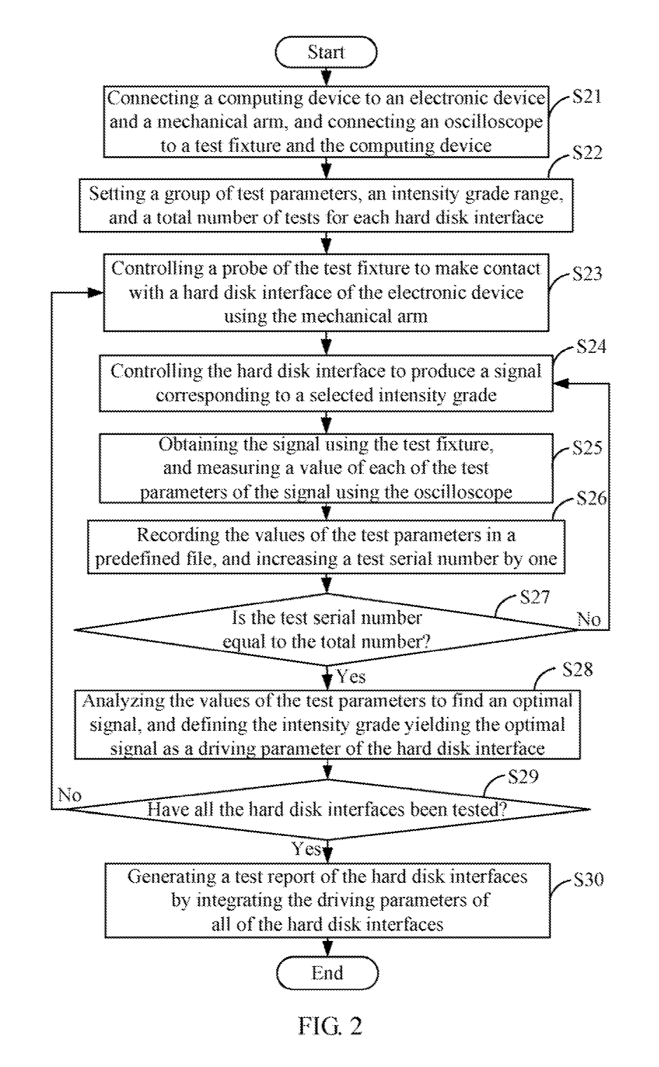

FIG. 2 is a flowchart of one embodiment of a method for testing the integrity of signals transmitted from the hard disk interfaces 20 of the electronic device 2, using the computing device 1. Depending on the embodiment, additional steps may be added, others removed, and the ordering of the steps may be changed.

In step S21, a test operator connects the computing device 1 to the electronic device 2 and the mechanical arm 4, and connects the oscilloscope 3 to the computing device 1 and the test fixture 5. In the embodiment, the computing device 1 is connected to the electronic device 2 through the serial port, and is connected to the oscilloscope 3 through the first general purpose interface bus (GPIB). The mechanical arm 4 is equipped with the test fixture 5 having the probe 50. The test fixture 5 is connected to the oscilloscope 3 through the second GPIB.

In step S22, the parameter setting module 101 sets a group of test parameters for evaluating the integrity of signals transmitted from the hard disk interfaces 20; and also sets an intensity grade range for the signals, and a total number (denoted as “X”) of tests for testing the signal of each hard disk interface 20. As mentioned above, the test parameters may include a phase value, a jitter value, a period value, a frequency value, and a rising time and a falling time of the signal of each hard disk interface 20. The intensity grade range for the signals encompasses a finite set of different intensity characteristics of the signals, with each intensity characteristic having a predefined graded scale. In one embodiment, the intensity grade range includes a phase grade range, a jitter grade range, and a signal emphasis grade range of the signals.

In step S23, the arm control module 102 controls the probe 50 of the test fixture 5 to make contact with one of the hard disk interfaces 20 to be tested using the mechanical arm 4. In the embodiment, the arm control module 102 generates a command to drive the mechanical arm 4 to control the probe 50 of the test fixture 5 to touch the hard disk interface 20.

In step S24, the signal measuring module 103 adjusts the intensity grade of the signal transmitted through the hard disk interface 20, and thereby controls the hard disk interface 20 to produce a signal corresponding to the adjusted intensity grade. Once the signal corresponding to the adjusted intensity grade is generated, in one embodiment, the signal measuring module 103 can increase the intensity grade of the signal by strengthening the signal, and decrease the intensity grade of the signal by weakening the signal. Thus the intensity grade of the signal can be adjusted to a selected grade in the graded scale among any of the phase grade range, the jitter grade range, and the signal emphasis grade range.

In step S25, the signal measuring module 103 controls the test fixture 5 to obtain the signal generated by the hard disk interface 20, and measures a value of each of the test parameters of the signal using the oscilloscope 3.

In step S26, the signal measuring module 103 records the measured values of the test parameters in a predefined file, such as an EXCEL format file. The signal measuring module 103 also increases a test serial number (denoted generically as “Y”) by one, i.e., Y′=Y+1, when each set of measured values of the test parameters are recorded in the predefined file.

In step S27, the signal measuring module 103 determines whether the latest test serial number Y′ is equal to the total number X of tests. If the latest test serial number Y′ is not equal to the total number X, the procedure returns to step S24, i.e., to adjust the intensity grade of the signal to another selected grade in the graded scale among one of the phase grade range, the jitter grade range, and the signal emphasis grade range. If the latest test serial number Y′ is equal to the total number X, step S28 is implemented.

In step S28, the signal analyzing module 104 analyzes the measured values of the test parameters of the hard disk interface 20 to find a form of the signal which has an optimal signal integrity, determines which intensity grade yielded the form of the signal with the optimal signal integrity, and defines that intensity grade as a driving parameter of the hard disk interface 20. In the embodiment, the form of the signal which has the optimal signal integrity is defined as the form of the signal which has a minimum jitter value or a minimum phase value.

In step S29, the signal measuring module 103 determines whether all of the hard disk interfaces 20 have been tested. If any of the hard disk interfaces 20 have not been tested, the procedure returns to step S23. If all of the hard disk interfaces 20 have been tested, step S30 is implemented.

In step S30, the report generating module 105 generates a test report of the hard disk interfaces 20 by integrating the defined driving parameters of all of the hard disk interfaces 20, stores the test report of the hard disk interfaces 20 in the storage system 12, and displays the test report of the hard disk interfaces 20 on the display device 13.

Although certain embodiments have been specifically described, the present disclosure is not to be construed as being limited thereto. Various changes or modifications may be made to the embodiments without departing from the scope and spirit of the present disclosure.

What is claimed is:

1. A computing device, the computing device connected to an electronic device having a plurality of hard disk interfaces, to an oscilloscope, and to a mechanical arm that is equipped with a test fixture, the computing device comprising:
a storage system;
at least one processor; and
one or more programs stored in the storage system and executable by the at least one processor, the one or more programs comprising:
a parameter setting module that sets a group of test parameters for evaluating the integrity of signals transmitted from the hard disk interfaces, and sets an intensity grade range for the signals and a total number of tests for testing each of the hard disk interfaces;
an arm control module that controls a probe of the test fixture to make contact with a selected one of the hard disk interfaces using the mechanical arm;
a signal measuring module that adjusts an intensity grade of one of the signals transmitted through the selected hard disk interface and thereby controls the hard disk interface to produce a signal corresponding to the adjusted intensity grade, controls the test fixture to obtain the signal produced by the hard disk interface, and measures a value of each of the test parameters of the signal using the oscilloscope;
a signal analyzing module that analyzes the measured values of the test parameters of the hard disk interface to find a form of the signal which has an optimal signal integrity, determines which intensity grade yielded the form of the signal with the optimal signal integrity, and defines that intensity grade as a driving parameter of the hard disk interface; and
a report generating module that generates a test report of the hard disk interfaces by integrating the driving parameters of all of the hard disk interfaces, and displays the test report of the hard disk interfaces on a display device of the computing device.

2. The computing device according to claim 1, wherein the computing device electronically connects to the oscilloscope through a first general purpose interface bus (GPIB), and the test fixture electronically connects to the oscilloscope through a second GPIB.

3. The computing device according to claim 1, wherein the signal measuring module further records the values of the test parameters in a predefined file, and increases a test serial number by one when the values of the test parameters are recorded in the predefined file.

4. The computing device according to claim 3, wherein the signal measuring module further determines whether the test latest serial number is equal to the total number, and continues to adjust the intensity grade of the signal for measuring the test parameters of the signal until the latest test serial number is equal to the total number.

5. The computing device according to claim 1, wherein the signal measuring module further determines whether all of the hard disk interfaces have been tested, and the arm control module further controls the probe of the test fixture to contact with a next hard disk interface of the electronic device using the mechanical arm until all of the hard disk interfaces have been tested.

6. The computing device according to claim 1, wherein each of the hard disk interfaces is a serial attached small computer system (SAS) interface or a serial advanced technology attachment (SATA) interface.

7. The computing device according to claim 1, wherein the intensity grade range of the signals includes a phase grade range, a jitter grade range, and a signal emphasis grade range of the signals.

8. A method for testing integrity of signals transmitted from hard disk interfaces using a computing device, the computing device connected to an oscilloscope and to a mechanical arm that is equipped with a test fixture, the method comprising steps of:
setting a group of test parameters for evaluating the integrity of signals transmitted from the hard disk interfaces, and setting an intensity grade range for the signals and a total number of tests for testing each of the hard disk interfaces;
controlling a probe of the test fixture to make contact with one of the hard disk interfaces using the mechanical arm;
adjusting an intensity grade of the signals transmitted through the hard disk interface, and thereby controlling the hard disk interface to produce a signal corresponding to the adjusted intensity grade;
controlling the test fixture to obtain the signal produced by the hard disk interface, and measuring a value of each of the test parameters of the signal using the oscilloscope;
analyzing the measured values of the test parameters of the hard disk interface to find a form of the signal which has an optimal signal integrity;
determining which intensity grade yielded the form of the signal with the optimal signal integrity;
defining the determined intensity grade as a driving parameter of the hard disk interface;
generating a test report of the hard disk interfaces by integrating the driving parameters of all of the hard disk interfaces; and
displaying the test report of the hard disk interfaces on a display device of the computing device.

9. The method according to claim 8, wherein the computing device electronically connects to the oscilloscope through a first general purpose interface bus (GPIB), and the test fixture electronically connects to the oscilloscope through a second GPIB.

10. The method according to claim 8, further comprising:
recording the values of the test parameters in a predefined file, and increasing a test serial number by one when the values of the test parameters are recorded in the predefined file.

11. The method according to claim 10, further comprising:
determining whether the test serial number is equal to the total number; and
repeating from the adjusting step to the defining step until the test serial number is equal to the total number.

12. The method according to claim 8, further comprising:
determining whether all of the hard disk interfaces have been tested; and
repeating from the controlling step to the defining step until all of the hard disk interfaces have been tested.

13. The method according to claim 8, wherein each of the hard disk interfaces is a serial attached small computer system (SAS) interface or a serial advanced technology attachment (SATA) interface.

14. The method according to claim 8, wherein the intensity grade range of the signals includes a phase grade range, a jitter grade range, and a signal emphasis grade range of the signals.

15. A non-transitory computer-readable storage medium having stored thereon instructions that, when executed by at least one processor of a computing device, causes the computing device to perform a method for testing integrity of signals transmitted from hard disk interfaces, the computing device connected to an oscilloscope and to a mechanical arm that is equipped with a test fixture, the method comprising steps of:
setting a group of test parameters for evaluating the integrity of signals transmitted from the hard disk interfaces, and setting an intensity grade range for the signals and a total number of tests for testing each of the hard disk interfaces;
controlling a probe of the test fixture to make contact with one of the hard disk interfaces using the mechanical arm;
adjusting an intensity grade of the signals transmitted through the hard disk interface, and thereby controlling the hard disk interface to produce a signal corresponding to the adjusted intensity grade;
obtaining the signal produced by the hard disk interface using the test fixture, and measuring a value of each of the test parameters of the signal using the oscilloscope;
analyzing the measured values of the test parameters of the hard disk interface to find a form of the signal which has an optimal signal integrity;
determining which intensity grade yielded the form of the signal with the optimal signal integrity;
defining the determined intensity grade as a driving parameter of the hard disk interface;
generating a test report of the hard disk interfaces by integrating the driving parameters of all of the hard disk interfaces; and
displaying the test report of the hard disk interfaces on a display device of the computing device.

16. The storage medium according to claim 15, wherein the computing device electronically connects to the oscilloscope through a first general purpose interface bus (GPIB), and the test fixture electronically connects to the oscilloscope through a second GPIB.

17. The storage medium according to claim 15, wherein the method further comprises:
recording the values of the test parameters in a predefined file, and increasing a test serial number by one when the values of the test parameters are recorded in the predefined file.

18. The storage medium according to claim 17, wherein the method further comprises:
determining whether the test serial number is equal to the total number; and
repeating from the adjusting step to the defining step until the test serial number is equal to the total number.

19. The storage medium according to claim 15, wherein the method further comprises:
determining whether all of the hard disk interfaces have been tested; and
repeating from the controlling step to the defining step until all of the hard disk interfaces have been tested.

20. The storage medium according to claim 15, wherein each of the hard disk interfaces is a serial attached small computer system (SAS) interface or a serial advanced technology attachment (SATA) interface.
